(19) United States
(12) Patent Application Publication
(10) Pub. No.: US 2011/0278594 A1
(43) Pub. Date: Nov. 17, 2011

(54) METHOD FOR MANUFACTURING SILICON CARBIDE SUBSTRATE, METHOD FOR MANUFACTURING SEMICONDUCTOR DEVICE, SILICON CARBIDE SUBSTRATE, AND SEMICONDUCTOR DEVICE

(75) Inventors: Taro NISHIGUCHI, Itami-shi (JP); Makoto SASAKI, Itami-shi (JP); Shin HARADA, Osaka-shi (JP); Kyoko OKITA, Itami-shi (JP); Hiroki INOUE, Itami-shi (JP); Yasuo NAMIKAWA, Itami-shi (JP)

(73) Assignee: SUMITOMO ELECTRIC INDUSTRIES, LTD., Osaka-shi (JP)

(21) Appl. No.: 13/104,247

(22) Filed: May 10, 2011

(30) Foreign Application Priority Data
May 14, 2010 (JP) 2010-111976

(51) Int. Cl. H01L 29/12; C30B 23/02; H01L 21/20; B32B 13/04

(52) U.S. Cl. 257/77; 428/446; 117/106; 438/478; 257/E21.09; 257/E29.068

(57) ABSTRACT

A method for manufacturing a silicon carbide substrate includes the steps of: preparing a SiC substrate made of single-crystal silicon carbide; disposing a base substrate in a crucible so as to face a main surface of the SiC substrate; and forming a base layer made of silicon carbide in contact with the main surface of the SiC substrate by heating the base substrate in the crucible to fall within a range of temperature equal to or higher than a sublimation temperature of silicon carbide constituting the base substrate. The crucible has an inner wall at least a portion of which is provided with a coating layer made of silicon carbide.

### BACKGROUND OF THE INVENTION

1. Field of the Invention

The present invention relates to a method for manufacturing a silicon carbide substrate, a method for manufacturing a semiconductor device, a silicon carbide substrate, and a semiconductor device, more particularly, a method for manufacturing a silicon carbide substrate, a method for manufacturing a semiconductor device, a silicon carbide substrate, and a semiconductor device, each of which allows for reduced manufacturing cost of a semiconductor device that employs a silicon carbide substrate.

2. Description of the Background Art

In recent years, in order to achieve high reverse breakdown voltage, low loss, and utilization of semiconductor devices under a high temperature environment, silicon carbide has begun to be adopted as a material for a semiconductor device. Silicon carbide is a wide band gap semiconductor having a band gap larger than that of silicon, which has been conventionally widely used as a material for semiconductor devices. Hence, by adopting silicon carbide as a material for a semiconductor device, the semiconductor device can have a high reverse breakdown voltage, reduced on-resistance, and the like. Further, the semiconductor device thus adopting silicon carbide as its material has characteristics less deteriorated even under a high temperature environment than those of a semiconductor device adopting silicon as its material, advantageously.

Under such circumstances, various silicon carbide crystals used in manufacturing of semiconductor devices and methods for manufacturing silicon carbide substrates have been considered and various ideas have been proposed (for example, see Japanese Patent Laying-Open No. 2002-280531 (Patent Document 1)).

However, silicon carbide does not have a liquid phase at an atmospheric pressure. In addition, crystal growth temperature thereof is 2000° C. or greater, which is very high. This makes it difficult to control and stabilize growth conditions. Accordingly, it is difficult for a silicon carbide single-crystal to have a large bore diameter while maintaining its quality to be high. Hence, it is not easy to obtain a high-quality silicon carbide substrate having a large bore diameter. This difficulty in fabricating such a silicon carbide substrate having a large bore diameter results in not only increased manufacturing cost of the silicon carbide substrate but also fewer semiconductor devices produced for one batch using the silicon carbide substrate. Accordingly, manufacturing cost of the semiconductor devices is increased, disadvantageously. It is considered that the manufacturing cost of the semiconductor devices can be reduced by effectively utilizing a silicon carbide single-crystal, which is high in manufacturing cost, as a substrate.

### SUMMARY OF THE INVENTION

In view of this, an object of the present invention is to provide a method for manufacturing a silicon carbide substrate, a method for manufacturing a semiconductor device, a silicon carbide substrate, and a semiconductor device, each of which allows for reduced manufacturing cost of a semiconductor device that employs a silicon carbide substrate.

A method for manufacturing a silicon carbide substrate in accordance with the present invention includes the steps of preparing a SiC substrate made of single-crystal silicon carbide; disposing a silicon carbide source in a container so as to face a main surface of the SiC substrate; and forming a base layer made of silicon carbide in contact with the main surface of the SiC substrate by heating the silicon carbide source in the container to fall within a range of temperature equal to or higher than a sublimation temperature of silicon carbide constituting the silicon carbide source. The container has an inner wall, at least a portion of which is provided with a coating layer made of silicon carbide.

As described above, it is difficult for a high-quality silicon carbide single-crystal to have a large bore diameter. Meanwhile, for efficient manufacturing in a process of manufacturing a semiconductor device using a silicon carbide substrate, a substrate provided with predetermined uniform shape and size is required. Hence, even when a high-quality silicon carbide single-crystal (for example, silicon carbide single-crystal having a small defect density) is obtained, a region that cannot be processed into such a predetermined shape and the like by cutting, etc., may not be effectively used.

To address this, in the method for manufacturing the silicon carbide substrate in the present invention, the base layer is formed in contact with the main surface of the SiC substrate made of single-crystal silicon carbide. Hence, for example, a high-quality silicon carbide single-crystal not having a desired shape and the like is employed as the SiC substrate, while an inexpensive, low-quality base layer formed of silicon carbide crystal and having a large defect density is formed to have the above-described predetermined shape and size. The silicon carbide substrate obtained in such a process has the predetermined uniform shape and size as a whole. This contributes to improved efficiency in manufacturing semiconductor devices. Further, in the silicon carbide substrate manufactured in such a process, there is used the SiC substrate formed of the high-quality silicon carbide single-crystal, which has not been utilized conventionally because it cannot be processed into a desired shape and the like. Using such a SiC substrate, semiconductor devices can be manufactured, thus effectively using the silicon carbide single-crystal.

As described above, according to the method for manufacturing the silicon carbide substrate in the present invention, there can be provided a method for manufacturing a silicon carbide substrate to allow for reduced cost of manufacturing semiconductor devices using the silicon carbide substrate.

Further, in the method for manufacturing the silicon carbide substrate, the step of forming the base layer may not proceed sufficiently. The present inventor has studied and found that this is due to the following reason. That is, the formation of the base layer is accomplished by heating the silicon carbide source to fall within the range of temperature equal to or higher than the sublimation temperature of silicon carbide constituting the base substrate. Here, the formation of the base layer is achieved as follows: silicon carbide constituting the silicon carbide source is sublimated to be a sublimation gas, which is then recrystallized on the SiC substrate.

This sublimation gas is a gas formed by sublimation of solid silicon carbide, and includes Si, Si₂C, SiC₂, and the like, for example. However, when vapor pressure of the sublimation gas in the container for formation of the base layer is smaller than the saturated vapor pressure, silicon, which is higher in vapor pressure than carbon, is selectively (preferentially) desorbed from the silicon carbide. This results in carbonization (graphitization) in the vicinity of a surface of the silicon carbide source. Accordingly, the sublimation of silicon carbide is prevented, whereby the formation of the base layer is less likely to proceed.

To address this, in the method for manufacturing the silicon carbide substrate in the present invention, the container used to attain the formation of the base layer has the inner wall at least a portion of which is provided with the coating layer made of silicon carbide. Accordingly, silicon carbide constituting the coating layer is sublimated to increase the vapor pressure of the sublimation gas. This restrains the surface of the silicon carbide source from being carbonized due to the above-described selective desorption of silicon. Accordingly, the formation of the base layer resulting from the sublimation and recrystallization of silicon carbide source proceeds well.

In the method for manufacturing the silicon carbide substrate, the coating layer may be formed all over the inner wall of the container. This securely achieves increase of the vapor pressure of the sublimation gas, thereby further restraining carbonization of the silicon carbide source. Accordingly, the formation of the base layer resulting from the sublimation and recrystallization of the silicon carbide source proceed more satisfactorily.

In the method for manufacturing the silicon carbide substrate, the coating layer may have a thickness of not less than 1 μm. With this, the increase of the vapor pressure of the sublimation gas can be achieved more securely, thereby restraining carbonization of the silicon carbide source. Accordingly, the formation of the base layer resulting from the sublimation and recrystallization of the silicon carbide source proceeds more satisfactorily.

In the method for manufacturing the silicon carbide substrate, in the step of forming the base layer, the coating layer may be heated to fall within a range of temperature higher than that of the silicon carbide source. In this way, the formation of the base layer can be implemented in increased vapor pressure of the sublimation gas resulting from the generation of the sublimation gas from the coating layer. Accordingly, the formation of the base layer resulting from the sublimation and recrystallization of the silicon carbide source proceeds more satisfactorily.

In the above-described method for manufacturing the silicon carbide substrate, graphite may be employed as a material to form the container.

Graphite is not only stable under a high temperature but also is readily processed and is relatively low in its material cost. Hence, graphite is suitable for the material of the container used in the step in which the silicon carbide source needs to be heated to fall within the range of temperature equal to or higher than the sublimation temperature of silicon carbide.

In the method for manufacturing the silicon carbide substrate, in the step of preparing the SiC substrate, a plurality of the SiC substrates may be prepared, in the step of disposing the silicon carbide source, the silicon carbide source may be disposed with the plurality of the SiC substrates being arranged side by side when viewed in a planar view, and in the step of forming the base layer, the base layer may be formed to connect the main surfaces of the plurality of the SiC substrates to one another.

As described above, it is difficult for a high-quality silicon carbide single-crystal to have a large bore diameter. To address this, the plurality of SiC substrates each obtained from a high-quality silicon carbide single-crystal are placed and arranged side by side when viewed in a planar view, and then the base layer is formed such that the main surfaces of the plurality of SiC substrates are connected to one another, thereby obtaining a silicon carbide substrate that can be handled as a substrate having a high-quality SiC layer and a large bore diameter. By using such a silicon carbide substrate, the process of manufacturing a semiconductor device can be improved in efficiency. It should be noted that in order to improve the efficiency of the process of manufacturing a semiconductor device, it is preferable that adjacent ones of the plurality of SiC substrates are arranged in contact with one another. More specifically, for example, the plurality of SiC substrates are preferably arranged in contact with one another in the form of a matrix.

In the method for manufacturing the silicon carbide substrate, in the step of disposing the silicon carbide source, as the silicon carbide source, a base substrate made of silicon carbide may be disposed such that a main surface of the base substrate and the main surface of the SiC substrate face and make contact with each other, and in the step of forming the base layer, the base layer may be formed by heating the base substrate to connect the base substrate to the SiC substrate. By thus adopting the base substrate made of silicon carbide as the silicon carbide source, the base layer can be formed readily.

The method for manufacturing the silicon carbide substrate may further include the step of smoothing the main surfaces of the base substrate and the SiC substrate which are to be brought into contact with each other in the step of disposing the silicon carbide source, before the step of disposing the silicon carbide source. By thus smoothing the surfaces, which are to be the connection surface between the base substrate and the SiC substrate, the base substrate and the SiC substrate can be connected to each other more securely.

In the method for manufacturing the silicon carbide substrate, the step of disposing the silicon carbide source may be performed without polishing, before the step of disposing the silicon carbide source, the main surfaces of the base substrate and the SiC substrate which are to be brought into contact with each other in the step of disposing the silicon carbide source.

Accordingly, the manufacturing cost of the silicon carbide substrate can be reduced. Here, as described above, the main surfaces of the base substrate and the SiC substrate, which are to be brought into contact with each other in the step of disposing the silicon carbide source, may not be polished. However, for removal of damaged layers in the vicinity of surfaces formed by slicing upon fabricating the substrate, it is preferable to perform the step of disposing the silicon carbide source after performing a step of removing the damaged layers by means of etching, for example.

In the method for manufacturing the silicon carbide substrate, in the step of disposing the silicon carbide source, as the silicon carbide source, a material substrate made of silicon carbide may be disposed such that a main surface of the material substrate and the main surface of the SiC substrate face each other with a space therebetween, and in the step of forming the base layer, the base layer may be formed by heating the material substrate to sublimate silicon carbide constituting the material substrate.

By thus adopting the material substrate made of silicon carbide as the silicon carbide source, the base layer can be formed readily.

In the method for manufacturing the silicon carbide substrate, in the step of forming the base layer, it is preferable that the silicon carbide source is heated to a temperature higher than that of the SiC substrate. Accordingly, silicon carbide constituting the silicon carbide source of the SiC substrate and the silicon carbide source is mainly sublimated and recrystallized. As a result, the base layer can be formed while maintaining quality of the SiC substrate such as crystallinity.

In the method for manufacturing the silicon carbide substrate, in the step of forming the base layer, the base layer may be formed such that an opposite main surface of the SiC substrate to the base layer has an off angle of not less than 50° and not more than 65° relative to a {0001} plane.

By growing single-crystal silicon carbide of hexagonal system in the <0001> direction, a high-quality single-crystal can be fabricated efficiently. From such a silicon carbide single-crystal grown in the <0001> direction, a silicon carbide substrate having a main surface corresponding to the {0001} plane can be obtained efficiently. Meanwhile, by using a silicon carbide substrate having a main surface having an off angle of not less than 50° and not more than 65° relative to the plane orientation of {0001}, a semiconductor device with high performance may be manufactured.

Specifically, for example, it is general that a silicon carbide substrate used in fabricating a MOSFET (Metal Oxide Semiconductor Field Effect Transistor) has a main surface having an off angle of approximately 8° or smaller relative to the plane orientation of {0001}. An epitaxial growth layer is formed on this main surface and an oxide film, an electrode, and the like are formed on this epitaxial growth layer, thereby obtaining a MOSFET. In this MOSFET, a channel region is formed in a region including an interface between the epitaxial growth layer and the oxide film. However, in the MOSFET having such a structure, a multiplicity of interface states are formed around the interface between the epitaxial growth layer and the oxide film, i.e., the location in which the channel region is formed, due to the substrate's main surface having an off angle of approximately 8° or smaller relative to the {0001} plane. This hinders traveling of carriers, thus decreasing channel mobility.

To address this, in the step of forming the base layer, the SiC substrate has a main surface opposite to the base layer and having an off angle of not less than 50° and not more than 65° relative to a {0001} plane, whereby the main surface of the silicon carbide substrate to be manufactured will have an off angle of not less than 50° and not more than 65° relative to the {0001} plane. This reduces the formation of the interface states. Accordingly, a silicon carbide substrate can be manufactured which allows for fabrication of a MOSFET having reduced on-resistance.

In the method for manufacturing the silicon carbide substrate, in the step of forming the base layer, the base layer may be formed such that the opposite main surface of the SiC substrate to the base layer has an off orientation forming an angle of not more than 5° relative to a <1-100> direction.

The <1-100> direction is a representative off orientation in a silicon carbide substrate. Variation in the off orientation resulting from variation in the slicing process of the process of manufacturing the substrate is adapted to be not more than 5°, which allows an epitaxial growth layer to be formed readily on the silicon carbide substrate.

In the method for manufacturing the silicon carbide substrate, in the step of forming the base layer, the base layer may be formed such that the opposite main surface of the SiC substrate to the base layer has an off angle of not less than −3° and not more than 5° relative to a {03-38} plane in the <1-100> direction.

Accordingly, channel mobility can be further improved in the case where a MOSFET or the like is fabricated using the silicon carbide substrate. Here, setting the off angle at not less than −3° and not more than +5° relative to the plane orientation of {03-38} is based on a fact that particularly high channel mobility was obtained in this set range as a result of inspecting a relation between the channel mobility and the off angle.

Further, the “off angle relative to the {03-38} plane in the <1-100> direction” refers to an angle formed by an orthogonal projection of a normal line of the above-described main surface to a flat plane defined by the <1-100> direction and the <0001> direction, and a normal line of the {03-38} plane. The sign of positive value corresponds to a case where the orthogonal projection approaches in parallel with the <1-100> direction whereas the sign of negative value corresponds to a case where the orthogonal projection approaches in parallel with the <0001> direction.

It should be noted that the main surface preferably has a plane orientation of substantially {03-38}, and the main surface more preferably has a plane orientation of {03-38}. Here, the expression “the main surface has a plane orientation of substantially {03-38}” is intended to encompass a case where the plane orientation of the main surface of the substrate is included in a range of off angle such that the plane orientation can be substantially regarded as {03-38} in consideration of processing accuracy of the substrate. In this case, the range of off angle is, for example, a range of off angle of ±2° relative to {03-38}. Accordingly, the above-described channel mobility can be further improved.

In the method for manufacturing the silicon carbide substrate, in the step of forming said base layer, the base layer may be formed such that the opposite main surface of the SiC substrate to the base layer has an off orientation forming an angle of not more than 5° relative to a <11-20> direction.

The <11-20> direction is a representative off orientation in a silicon carbide substrate, as with the <1-100> direction. Variation in the off orientation resulting from variation in the slicing process of the process of manufacturing the substrate is adapted to be ±5°, which allows an epitaxial growth layer to be formed readily on the silicon carbide substrate.

In the method for manufacturing the silicon carbide substrate, in the step of forming the base layer, the base layer may be formed in an atmosphere obtained by reducing pressure of atmospheric air. Accordingly, the manufacturing cost of the silicon carbide substrate can be reduced.

In the method for manufacturing the silicon carbide substrate, in the step of forming the base layer, the base layer may be formed under a pressure higher than 10⁻¹ Pa and lower than 10⁴ Pa. Accordingly, the base layer can be formed using a simple device, and an atmosphere for accomplishing the formation of the base layer can be provided for a relatively short time. As a result, the manufacturing cost of the silicon carbide substrate can be reduced.

A method for manufacturing a semiconductor device in the present invention includes the steps of: preparing a silicon carbide substrate; forming an epitaxial growth layer on the silicon carbide substrate; and forming an electrode on the epitaxial growth layer. In the step of preparing the silicon carbide substrate, the silicon carbide substrate is manufactured using the above-described method for manufacturing the silicon carbide substrate in the present invention.

According to the method for manufacturing the semiconductor device in the present invention, the semiconductor device is manufactured using the silicon carbide substrate manufactured using the above-described method for manufacturing the silicon carbide substrate in the present invention. Accordingly, the manufacturing cost of the semiconductor device can be reduced.

A silicon carbide substrate according to the present invention is manufactured using the above-described method for manufacturing the silicon carbide substrate in the present invention. Accordingly, the silicon carbide substrate in the present invention allows for reduced cost in manufacturing semiconductor devices using the silicon carbide substrate.

A semiconductor device according to the present invention is manufactured using the method for manufacturing the semiconductor device of the present invention. Accordingly, the semiconductor device of the present invention is a semiconductor device manufactured with reduced cost.

As apparent from the description above, according to the method for manufacturing the silicon carbide substrate, the method for manufacturing the semiconductor device, the silicon carbide substrate, and the semiconductor device in the present invention, there can be provided a method for manufacturing a silicon carbide substrate, a method for manufacturing a semiconductor device, a silicon carbide substrate, and a semiconductor device, each of which allows for reduced manufacturing cost of a semiconductor device that employs a silicon carbide substrate.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a flowchart schematically showing a method for manufacturing a silicon carbide substrate.

FIG. 2 is a schematic cross sectional view for illustrating the method for manufacturing the silicon carbide substrate.

FIG. 3 is a schematic cross sectional view showing a structure of the silicon carbide substrate.

FIG. 4 is a flowchart schematically showing a method for manufacturing a silicon carbide substrate in a second embodiment.

FIG. 5 is a schematic cross sectional view for illustrating a method for manufacturing a silicon carbide substrate in the second embodiment.

FIG. 6 is a schematic cross sectional view for illustrating the method for manufacturing the silicon carbide substrate in the second embodiment.

FIG. 7 is a schematic cross sectional view for illustrating the method for manufacturing the silicon carbide substrate in the second embodiment.

FIG. 8 is a schematic cross sectional view for illustrating a method for manufacturing a silicon carbide substrate in a third embodiment.

FIG. 9 is a schematic cross sectional view showing a structure of the silicon carbide substrate in the third embodiment.

FIG. 10 is a schematic cross sectional view showing a structure of a vertical type MOSFET.

FIG. 11 is a flowchart schematically showing a method for manufacturing the vertical type MOSFET.

FIG. 12 is a schematic cross sectional view for illustrating the method for manufacturing the vertical type MOSFET.

FIG. 13 is a schematic cross sectional view for illustrating the method for manufacturing the vertical type MOSFET.

FIG. 14 is a schematic cross sectional view for illustrating the method for manufacturing the vertical type MOSFET.

FIG. 15 is a schematic cross sectional view for illustrating the method for manufacturing the vertical type MOSFET.

### DESCRIPTION OF THE PREFERRED EMBODIMENTS

The following describes embodiments of the present invention with reference to figures. It should be noted that in the below-mentioned figures, the same or corresponding portions are given the same reference characters and are not described repeatedly.

### First Embodiment

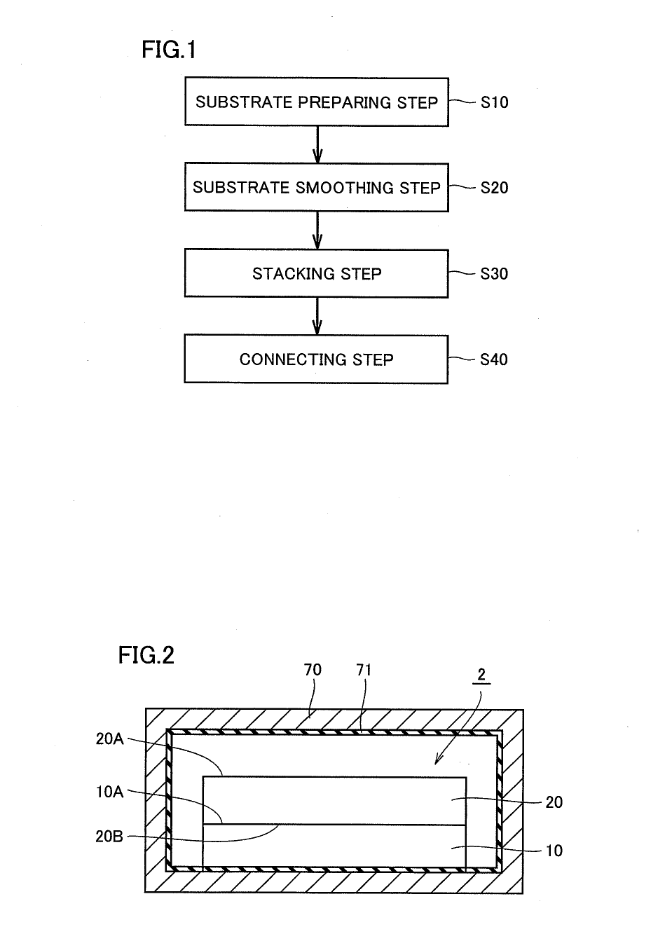

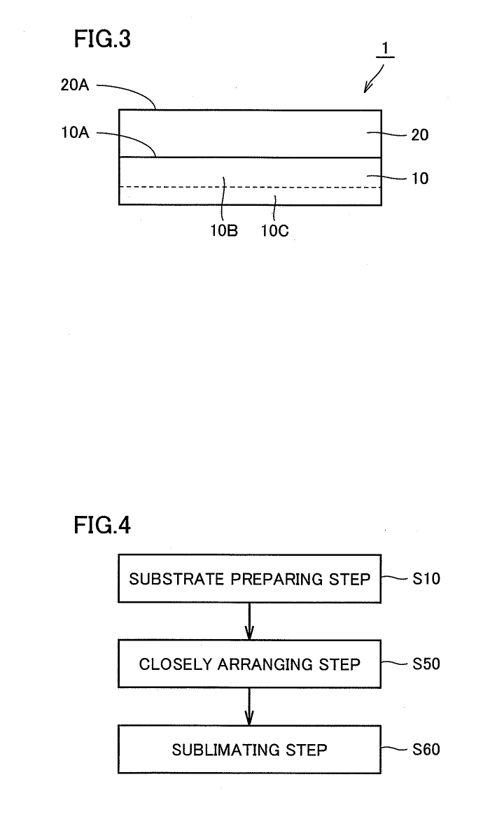

A first embodiment, which is one embodiment of the present invention, will be described first with reference to FIG. 1 and FIG. 2. Referring to FIG. 1, a substrate preparing step is first performed as a step (S10) in a method for manufacturing a silicon carbide substrate in the present embodiment. In this step (S10), referring to FIG. 2, a base substrate 10 formed of silicon carbide and a SiC substrate 20 formed of single-crystal silicon carbide are prepared. Base substrate 10 is a silicon carbide source in the present embodiment. SiC substrate 20 has a main surface 20A, which will be main surface 20A of a SiC layer 20 that will be obtained by this manufacturing method (see FIG. 3 described below). Hence, on this occasion, the plane orientation of main surface 20A of SiC substrate 20 is selected in accordance with a desired plane orientation of main surface 20A. Meanwhile, a substrate having an impurity concentration greater than, for example, 2×10¹⁹ cm⁻³ can be adopted as base substrate 10. Further, for SiC substrate 20, there can be used a substrate having an impurity concentration larger than 5×10¹⁸ cm⁻³ and smaller than 2×10¹⁹ cm⁻³. In this way, base layer 10 having a small resistivity can be formed while restraining generation of stacking fault at least in SiC layer 20 when providing heat treatment in a device process. Further, as base substrate 10, a substrate can be adopted which is formed of single-crystal silicon carbide, polycrystal silicon carbide, amorphous silicon carbide, a silicon carbide sintered compact, or the like.

Next, a substrate smoothing step is performed as a step (S20). In this step (S20), a main surface 10A of base substrate 10 and a main surface 20B of SiC substrate 20 (connection surface) are smoothed by, for example, polishing. Main surface 10A and main surface 20B are to be brought into contact with each other in a below-described step (S30). It should be noted that this step (S20) is not an essential step, but provides, if performed, a gap having a uniform size between base substrate 10 and SiC substrate 20, which are to face each other. Accordingly, in a below-described step (S40), uniformity is improved in reaction (connection) at the connection surface. This allows base substrate 10 and SiC substrate 20 to be connected to each other more securely. In order to connect base substrate 10 and SiC substrate 20 to each other further securely, the above-described connection surface preferably has a surface roughness Ra of less than 100 nm, more preferably, less than 50 nm. Further, by setting surface roughness Ra of the connection surface at less than 10 nm, more secure connection can be achieved.

Meanwhile, step (S20) may be omitted, i.e., step (S30) may be performed without polishing the main surfaces of base substrate 10 and SiC substrate 20, which are to be brought into contact with each other. This reduces manufacturing cost of silicon carbide substrate 1. Further, for removal of damaged layers located in surfaces formed by slicing upon fabrication of base substrate 10 and SiC substrate 20, a step of removing the damaged layers may be performed by, for example, etching instead of step (S20) or after step (S20), and then step (S30) described below may be performed.

Next, a stacking step is performed as step (S30). In this step (S30), in a crucible 70 serving as a container, base substrate 10 serving as the silicon carbide source is disposed to face the one main surface of SiC substrate 20 such that the one main surface 10A of base substrate 10 and the one main surface 20B of SiC substrate 20 face and make contact with each other. More specifically, referring to FIG. 2, SiC substrate 20 is placed on and in contact with main surface 10A of base substrate 10, thereby fabricating a stacked substrate 2. Crucible 70 has an inner wall on which a coating layer 71 made of silicon carbide is formed.

Here, main surface 20A of SiC substrate 20 opposite to base substrate 10 may have an off angle of not less than 50° and not more than 65° relative to the {0001} plane. In this way, a silicon carbide substrate 1 can be readily manufactured in which main surface 20A of SiC layer 20 has an off angle of not less than 50° and not more than 65° relative to the {0001} plane. Further, the off orientation of main surface 20A forms an angle of 5° or less relative to the <1-100> direction. This facilitates formation of an epitaxial growth layer on silicon carbide substrate 1 (main surface 20A) to be fabricated. Further, main surface 20A may have an off angle of not less than −3° and not more than 5° relative to the {03-38} plane in the <1-100> direction. This further improves channel mobility when fabricating a MOSFET using silicon carbide substrate 1 to be manufactured.

On the other hand, the off orientation of main surface 20A may form an angle of 5° or smaller relative to the <11-20> direction. This facilitates formation of an epitaxial growth layer on silicon carbide substrate 1 to be fabricated.

Next, as step (S40), a connecting step is performed. In this step (S40), base substrate 10 is heated in crucible 70 to fall within a range of temperature equal to or higher than the sublimation temperature of silicon carbide constituting base substrate 10, so as to form a base layer in contact with one main surface 20B of SiC substrate 20. Namely, by heating stacked substrate 2, base substrate 10 is connected to SiC substrate 20, thereby forming the base layer. On this occasion, coating layer 71 is also heated to a range of temperature equal to or higher than the sublimation temperature of silicon carbide constituting coating layer 71.

Here, referring to FIG. 2, crucible 70 can be made of a material such as graphite. By heating stacked substrate 2 to the range of temperature equal to or higher than the sublimation temperature of silicon carbide, base substrate 10 and SiC substrate 20 are connected to each other. Namely, the above-described connection is made in crucible 70 having its inner wall provided with coating layer 71 made of silicon carbide. With the above procedure, the method for manufacturing the silicon carbide substrate in the present embodiment is completed, thereby obtaining silicon carbide substrate 1 shown in FIG. 3.

It should be noted that the above-described method for manufacturing the silicon carbide substrate may further include a step of polishing the main surface of SiC substrate 20 that corresponds to main surface 20A of SiC substrate 20 opposite to base substrate 10 in stacked substrate 2. This allows a high-quality epitaxial growth layer to be formed on main surface 20A of SiC layer 20 (SiC substrate 20) opposite to base substrate 10. As a result, a semiconductor device can be manufactured which includes the high-quality epitaxial growth layer as an active layer, for example. Namely, by employing such a step, silicon carbide substrate 1 can be obtained which allows for manufacturing of a high-quality semiconductor device including the epitaxial layer formed on SiC layer 20. Here, main surface 20A of SiC substrate 20 may be polished after base substrate 10 and SiC substrate 20 are connected to each other. Alternatively, there may be polished in advance the main surface of SiC substrate 20 that is opposite to base substrate 10 and that is to be main surface 20A in the stacked substrate, thus performing the polishing before the step of fabricating the stacked substrate.

Referring to FIG. 3, silicon carbide substrate 1 obtained according to the above-described manufacturing method includes base layer 10 made of silicon carbide, and SiC layer 20 made of single-crystal silicon carbide different from that of base layer 10. Here, the expression “SiC layer 20 is made of single-crystal silicon carbide different from that of base layer 10” encompasses: a case where base layer 10 is made of silicon carbide, which is not of single-crystal such as polycrystal silicon carbide or amorphous silicon carbide; and a case where base layer 10 is made of single-crystal silicon carbide different in crystal from that of SiC layer 20. The expression “base layer 10 and SiC layer 20 are made of silicon carbide different in crystal” refers to, for example, a state in which a defect density in one side relative to a boundary between base layer 10 and SiC layer 20 is different from that in the other side. In this case, the defect densities may be discontinuous at the boundary.

In the method for manufacturing silicon carbide substrate 1 in the present embodiment, silicon carbide substrate 1 can be provided with desired shape and size by selecting the shape and the like of base substrate 10. Accordingly, silicon carbide substrate 1 can be manufactured which contributes to efficient manufacturing of semiconductor devices. Further, in silicon carbide substrate 1 manufactured in such a process, SiC substrate 20 is used. SiC substrate 20 is made of high-quality silicon carbide single-crystal, which has not been utilized conventionally because it cannot be processed into a desired shape and the like. Using such a SiC substrate, semiconductor devices can be manufactured, thus effectively using the silicon carbide single-crystal. As a result, according to the method for manufacturing silicon carbide substrate 1 in the present embodiment, there can be manufactured a silicon carbide substrate that allows for reduced cost of manufacturing semiconductor devices using the silicon carbide substrate.

Further, in the method for manufacturing silicon carbide substrate 1 in the present embodiment, coating layer 71 made of silicon carbide is formed all over the inner wall of crucible 70 serving as the container for use in attaining the connection. Thus, when silicon carbide constituting coating layer 71 is sublimated, vapor pressure of the sublimation gas is increased in crucible 70. Accordingly, surfaces of base substrate 10 and SiC substrate 20 are restrained from being carbonized (graphitized) due to selective desorption of silicon from base substrate 10 and SiC substrate 20. Accordingly, the connection resulting from the sublimation and recrystallization of silicon carbide is developed well between base substrate 10 and SiC substrate 20. It should be noted that the effect of restraining carbonization of the surfaces of base substrate 10 and SiC substrate 20 can be exhibited so far as coating layer 71 is formed on at least a portion of the inner wall of crucible 70. However, the effect can be exhibited more securely when coating layer 71 is formed all over the inner wall of crucible 70 as described above.

Further, coating layer 71 preferably has a thickness of 1 μm or greater. This securely achieves the increase of the vapor pressure of the sublimation gas, thereby further restraining the carbonization of the surfaces of base substrate 10 and SiC substrate 20. In order to maintain the stable increase of the vapor pressure of the sublimation gas for a long time, coating layer 71 preferably has a thickness of 100 μm or greater. On the other hand, in order to reduce the manufacturing cost of the coating layer, coating layer 71 preferably has a thickness of 1 mm or smaller and more preferably 400 μm or smaller.

Further, coating layer 71 can be formed by any method, and can be formed, for example, the following method. Namely, coating layer 71 can be formed by a CVD (Chemical Vapor Deposition) method. Accordingly, dense coating layer 71 can be formed. Further, in the case where crucible 70 serving as the container for use in the formation of the base layer is made of carbon (graphite), coating layer 71 may be formed by means of a process including the steps of: forming a silicon film on the inner wall of crucible 70; and carbonizing the silicon film by heating crucible 70 thus having the silicon film formed thereon. In this way, coating layer 71 can be obtained which is firmly connected to the inner wall of crucible 70. Further, coating layer 71 may be formed by means of a sputtering method. In this way, even when the inner wall of crucible 70 has a relatively complicated shape, coating layer 71 can be formed readily.

Further, in the method for manufacturing silicon carbide substrate 1 in the present embodiment, in step (S40), coating layer 71 may be heated to fall within a range of temperature higher than that of base substrate 10. Accordingly, the formation of base layer 10 can be implemented in increased vapor pressure of the sublimation gas resulting from the generation of the sublimation gas from coating layer 71. Accordingly, the connection resulting from the sublimation and recrystallization of silicon carbide is developed more between base substrate 10 and SiC substrate 20.

Further, in the method for manufacturing silicon carbide substrate 1 in the present embodiment, in step (S40), base substrate 10 may be heated to a temperature higher than that of SiC substrate 20. Accordingly, silicon carbide constituting base substrate 10 is mainly sublimated and recrystallized to achieve the connection between base substrate 10 and SiC substrate 20. As a result, silicon carbide substrate 1 can be manufactured while maintaining quality of SiC substrate 20 such as crystallinity.

Here, in the case where base substrate 10 is made of single-crystal silicon carbide, referring to FIG. 3, base layer 10 of the silicon carbide substrate to be obtained will be made of single-crystal silicon carbide. On the other hand, in the case where base substrate 10 is formed of polycrystal silicon carbide, amorphous silicon carbide, a silicon carbide sintered compact, or the like, silicon carbide constituting base substrate 10 and sublimated and recrystallized on SiC substrate 20 only forms a region which will be single-crystal layer 10B made of single-crystal silicon carbide. Namely, in such a case, referring to FIG. 3, there is obtained silicon carbide substrate 1 in which base layer 10 includes single-crystal layer 10B made of single-crystal silicon carbide so as to include main surface 10A facing SiC layer 20. In this case, for example, in an early stage of a process of manufacturing a semiconductor device using silicon carbide substrate 1, silicon carbide substrate 1 is maintained to have its large thickness and is therefore readily handled, and in the middle of the process of manufacturing, a non-single-crystal region 10C, i.e., region of base layer (base substrate) 10 other than single-crystal layer 10B, is removed, whereby only single-crystal layer 10B of base layer 10 can remain within the semiconductor device. In this way, a high-quality semiconductor device can be manufactured while facilitating handling of silicon carbide substrate 1 in the process of manufacturing.

Further, in the method for manufacturing silicon carbide substrate 1 in the present embodiment, in step (S40), the stacked substrate may be heated in an atmosphere obtained by reducing pressure of the atmospheric air. This reduces manufacturing cost of silicon carbide substrate 1.

Further, in the method for manufacturing silicon carbide substrate 1 in the present embodiment, in step (S40), the stacked substrate may be heated under a pressure higher than 10⁻¹ Pa and lower than 10⁴ Pa. This can accomplish the above-described connection using a simple device, and provide an atmosphere for accomplishing the connection for a relatively short time. As a result, the manufacturing cost of silicon carbide substrate 1 can be reduced.

Here, in the stacked substrate fabricated in step (S30), the gap formed between base substrate 10 and SiC substrate 20 is preferably 100 μm or smaller. Accordingly, in step (S40), uniform connection between base substrate 10 and SiC substrate 20 can be achieved.

Further, heating temperature for the stacked substrate in step (S40) is preferably not less than 1800° C. and not more than 2500° C. If the heating temperature is lower than 1800° C., it takes a long time to connect base substrate 10 and SiC substrate 20, which results in decreased efficiency in manufacturing silicon carbide substrate 1. On the other hand, if the heating temperature exceeds 2500° C., surfaces of base substrate 10 and SiC substrate 20 become rough, which may result in generation of a multiplicity of crystal defects in silicon carbide substrate 1 to be fabricated. In order to improve efficiency in manufacturing while restraining generation of defects in silicon carbide substrate 1, the heating temperature for the stacked substrate in step (S40) is set at not less than 1900° C. and not more than 2100° C.

Further, the atmosphere upon the heating in step (S40) may be inert gas atmosphere. In the case where the atmosphere is the inert gas atmosphere, the inert gas atmosphere preferably contains at least one selected from a group consisting of argon, helium, and nitrogen.

### Second Embodiment

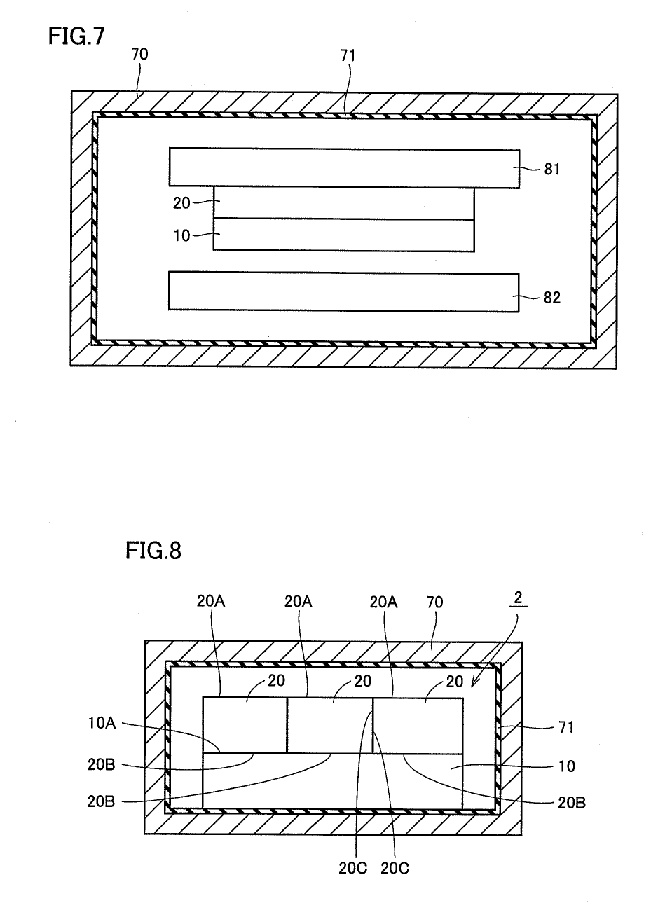

The following describes another embodiment of the present invention, i.e., a second embodiment, with reference to FIG. 4 and FIG. 7. A method for manufacturing a silicon carbide substrate in the second embodiment is performed in basically the same manner as that in the first embodiment. However, the method for manufacturing the silicon carbide substrate in the second embodiment is different from that in the first embodiment in terms of a process of forming the base layer.

Referring to FIG. 4, the substrate preparing step is first performed as step (S10) in the method for manufacturing the silicon carbide substrate in the second embodiment. In step (S10), SiC substrate 20 is prepared as with the first embodiment, and a material substrate 11 made of silicon carbide is prepared. Material substrate 11 may be formed of single-crystal silicon carbide, polycrystal silicon carbide, or amorphous silicon carbide, or may be a sintered compact of silicon carbide. Alternatively, instead of material substrate 11, material powders made of silicon carbide may be employed.

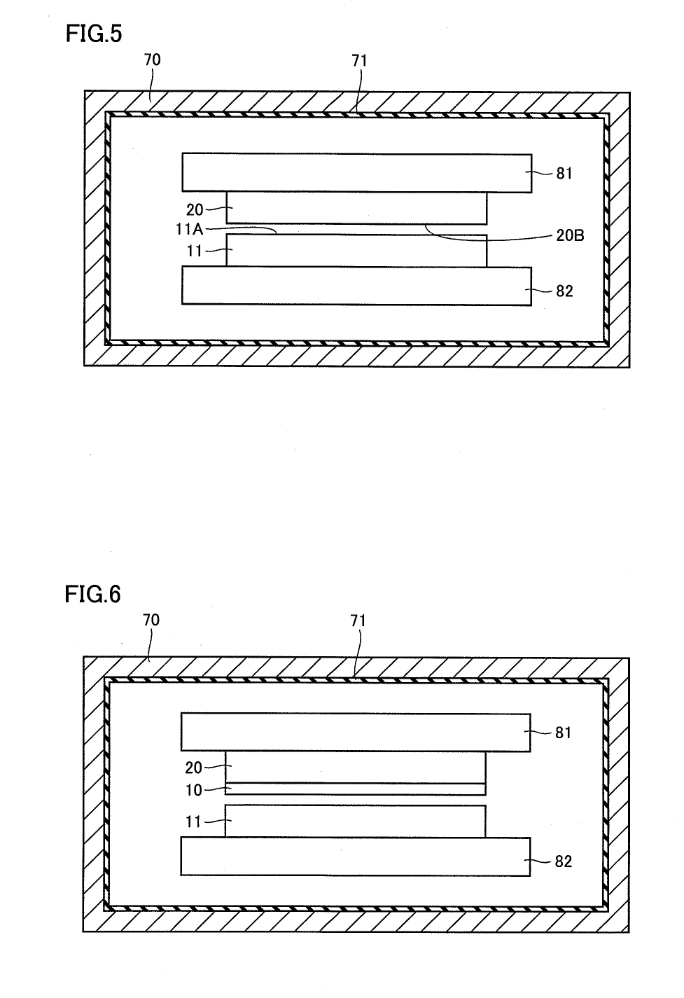

Next, as step (S50), a closely arranging step is performed. In step (S50), referring to FIG. 5, SiC substrate 20 and material substrate 11 are respectively retained to face each other by first heater 81 and second heater 82 arranged in heating container 70. Namely, in step (S50), material substrate 11 made of silicon carbide and serving as the silicon carbide source is disposed such that one main surface 11A of material substrate 11 and one main surface 20B of SiC substrate 20 face each other with a space therebetween.

It is considered that an appropriate value for the space between SiC substrate 20 and material substrate 11 is associated with the mean free path for sublimation gas to be obtained upon heating in a below-described step (S60). Specifically, the average value of the space between SiC substrate 20 and material substrate 11 can be set smaller than the mean free path for sublimation gas to be obtained in the below-described step (S60). For example, realistically, the space is preferably of several cm or smaller because a mean free path for atoms and molecules is approximately several cm to several ten cm at a pressure of 1 Pa and a temperature of 2000° C., although the mean free path depends on atomic radius and molecule radius. More specifically, SiC substrate 20 and material substrate 11 are closely arranged such that their main surfaces face each other with a space of not less than 1 μm and not more than 1 cm therebetween. Furthermore, when the average value of the space is 1 cm or smaller, the distribution in film thickness of base layer 10 to be formed in the below-described step (S60) can be reduced. Furthermore, when the average value of the space is 1 mm or smaller, the distribution in film thickness of base layer 10 to be formed in the below-described step (S60) can be reduced further. So far as the average value of the space is 1 μm or greater, a space for sublimation of silicon carbide can be sufficiently secured.

Next, sublimation step is performed as step (S60). In this step (S60), SiC substrate 20 is heated by first heater 81 to a predetermined substrate temperature. On the other hand, material substrate 11 is heated by second heater 82 to a predetermined material temperature. By heating material substrate 11 up to the material temperature on this occasion, silicon carbide is sublimated from the surface of the material substrate. Meanwhile, the substrate temperature is set lower than the material temperature. Specifically, for example, the substrate temperature is set lower than the material temperature by not less than 1° C. and not more than 100° C. or so. The substrate temperature is for example 1800° C. or greater and 2500° C. or smaller. Accordingly, as shown in FIG. 6, gas obtained through the sublimation of silicon carbide from material substrate 11 reaches the surface of SiC substrate 20 and is then formed into a solid form, thereby forming base layer 10. On this occasion, coating layer 71 is also heated to the range of temperature higher than the sublimation temperature of silicon carbide.

By maintaining this state, as shown in FIG. 7, all the SiC constituting material substrate 11 is sublimated and transferred onto the surface of SiC substrate 20. Accordingly, step (S60) is completed, thereby completing silicon carbide substrate 1 similar to that in the first embodiment described with reference to FIG. 3. Here, the predetermined space is formed between SiC substrate 20 and material substrate 11 as described above in the present embodiment. Hence, according to the method for manufacturing the silicon carbide substrate in the present embodiment, even when the material substrate serving as the silicon carbide source is formed of polycrystal silicon carbide, amorphous silicon carbide, a silicon carbide sintered compact, or the like, base layer 10 formed is made of single-crystal silicon carbide.

### Third Embodiment

The following describes still another embodiment of the present invention, i.e., a third embodiment. A method for manufacturing a silicon carbide substrate in the third embodiment is performed in basically the same procedure as that in the method for manufacturing the silicon carbide substrate in the first embodiment, and provides effects similar to those in the first embodiment. However, the method for manufacturing the silicon carbide substrate in the third embodiment is different from the method of the first embodiment in that in step (S30), a plurality of SiC substrates 20 are placed and arranged side by side when viewed in a planar view.

In other words, in the method for manufacturing the silicon carbide substrate in the present embodiment, in step (S10), base substrate 10 is first prepared as with the first embodiment and the plurality of SiC substrates 20 are prepared. Next, step (S20) is performed in the same way as in the first embodiment, as required. Thereafter, referring to FIG. 8, in step (S30), the plurality of SiC substrates 20 are placed and arranged side by side on main surface 10A of base substrate 10 when viewed in a planar view, so as to fabricate a stacked substrate. In other words, the plurality of SiC substrates 20 are disposed on and along main surface 10A of base substrate 10.

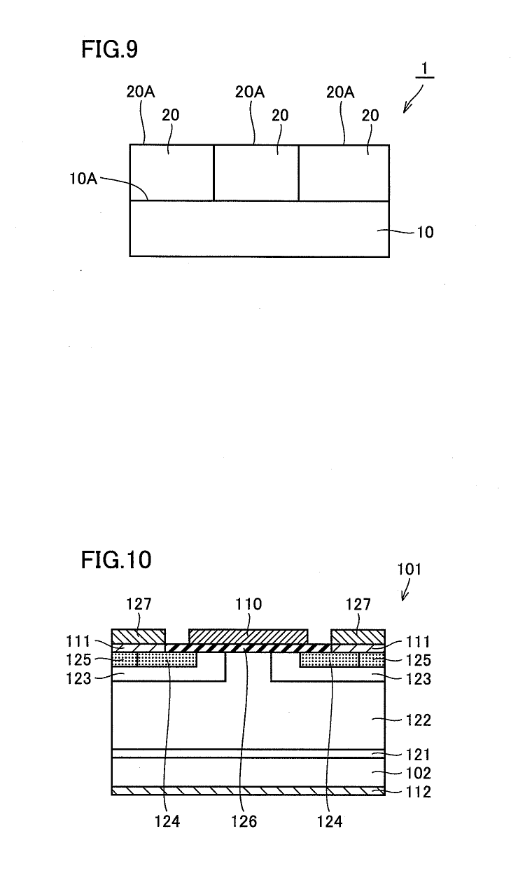

More specifically, SiC substrates 20 may be arranged on main surface 10A of base substrate 10 in the form of a matrix such that adjacent SiC substrates 20 are in contact with each other. Thereafter, step (S40) is performed in the same way as in the first embodiment to obtain silicon carbide substrate 1. In the present embodiment, in step (S30), the plurality of SiC substrates 20 are placed on base substrate 10, and the plurality of SiC substrates 20 and base substrate 10 are connected to one another in step (S40). Thus, referring to FIG. 9, the method for manufacturing the silicon carbide substrate in the present embodiment allows for manufacturing of silicon carbide substrate 1 that can be handled as a substrate having a high-quality SiC layer 20 and a large bore diameter. Utilization of such a silicon carbide substrate 1 allows for efficient manufacturing process of semiconductor devices.

Further, referring to FIG. 8, each of SiC substrates 20 preferably has an end surface 20C substantially perpendicular to main surface 20A of SiC substrate 20. In this way, silicon carbide substrate 1 can be readily formed. Here, for example, when end surface 20C and main surface 20A form an angle of not less than 85° and not more than 95°, it can be determined that end surface 20C and main surface 20A are substantially perpendicular to each other.

### Fourth Embodiment

As a fourth embodiment, the following describes one exemplary semiconductor device fabricated using the above-described silicon carbide substrate of the present invention. Referring to FIG. 10, a semiconductor device 101 according to the present invention is a DiMOSFET (Double Implanted MOSFET) of vertical type, and has a substrate 102, a buffer layer 121, a reverse breakdown voltage holding layer 122, p regions 123, n⁺ regions 124, p⁺ regions 125, an oxide film 126, source electrodes 111, upper source electrodes 127, a gate electrode 110, and a drain electrode 112 formed on the backside surface of substrate 102. Specifically, buffer layer 121 made of silicon carbide is formed on the front-side surface of substrate 102 made of silicon carbide of n type conductivity. Employed as substrate 102 is the silicon carbide substrate manufactured in accordance with a method for manufacturing a silicon carbide substrate in the present invention, i.e., method inclusive of those described in the first to third embodiments. In the case where silicon carbide substrate 1 in each of the first to third embodiments is employed, buffer layer 121 is formed on SiC layer 20 of silicon carbide substrate 1. Buffer layer 121 has n type conductivity, and has a thickness of, for example, 0.5 μm. Further, impurity with n type conductivity in buffer layer 121 has a concentration of, for example, 5×10¹⁷ cm⁻³. Formed on buffer layer 121 is reverse breakdown voltage holding layer 122. Reverse breakdown voltage holding layer 122 is made of silicon carbide of n type conductivity, and has a thickness of 10 μm, for example. Further, reverse breakdown voltage holding layer 122 includes an impurity of n type conductivity at a concentration of, for example, 5×10¹⁵ cm⁻³.

Reverse breakdown voltage holding layer 122 has a surface in which p regions 123 of p type conductivity are formed with a space therebetween. In each of p regions 123, an n⁺ region 124 is formed at the surface layer of p region 123. Further, at a location adjacent to n⁺ region 124, a p⁺ region 125 is formed. Oxide film 126 is formed to extend on n⁺ region 124 in one p region 123, p region 123, an exposed portion of reverse breakdown voltage holding layer 122 between the two p regions 123, the other p region 123, and n⁺ region 124 in the other p region 123. On oxide film 126, gate electrode 110 is formed. Further, source electrodes 111 are formed on n⁺ regions 124 and p⁺ regions 125. On source electrodes 111, upper source electrodes 127 are formed. Moreover, drain electrode 112 is formed on the backside surface of substrate 102, i.e., the surface opposite to its front-side surface on which buffer layer 121 is formed.

Semiconductor device 101 in the present embodiment employs, as substrate 102, the silicon carbide substrate manufactured in accordance with the method for manufacturing the silicon carbide substrate in the present invention, i.e., method inclusive of those described in the first to third embodiments. Namely, semiconductor device 101 includes: substrate 102 serving as the silicon carbide substrate; buffer layer 121 and reverse breakdown voltage holding layer 122 both serving as epitaxial growth layers formed on and above substrate 102; and source electrodes 111 formed on reverse breakdown voltage holding layer 122. Further, substrate 102 is manufactured in accordance with the method for manufacturing the silicon carbide substrate in the present invention. Here, as described above, the substrate manufactured in accordance with the method for manufacturing the silicon carbide substrate in the present invention allows for reduced manufacturing cost of semiconductor devices. Hence, semiconductor device 101 is manufactured with the reduced manufacturing cost.

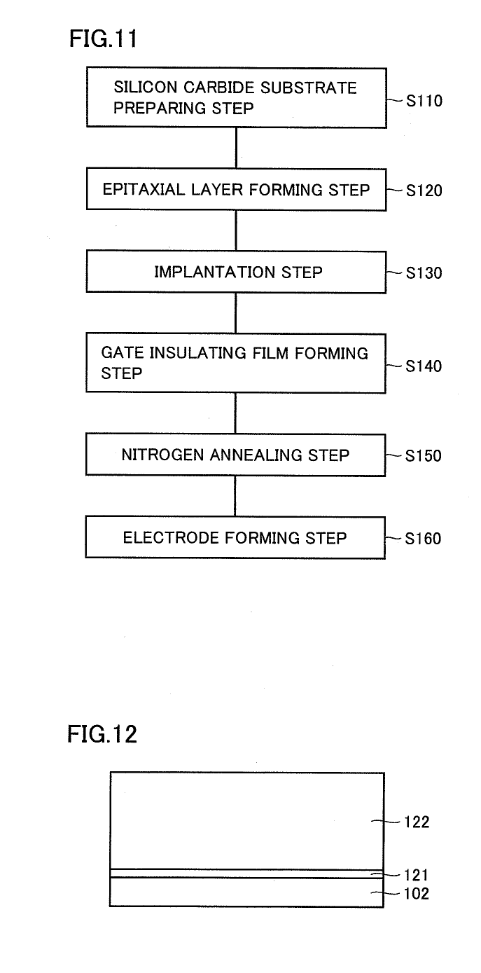

The following describes a method for manufacturing semiconductor device 101 shown in FIG. 10, with reference to FIG. 11-FIG. 15. Referring to FIG. 11, first, a silicon carbide substrate preparing step (S110) is performed. Prepared here is, for example, substrate 102, which is made of silicon carbide and has its main surface corresponding to the (03-38) plane (see FIG. 12). As substrate 102, there is prepared a silicon carbide substrate of the present invention, inclusive of silicon carbide substrate 1 manufactured in accordance with each of the manufacturing methods described in the first to third embodiments.

As substrate 102 (see FIG. 12), a substrate may be employed which has n type conductivity and has a substrate resistance of 0.02 Ωcm.

Next, as shown in FIG. 11, an epitaxial layer forming step (S120) is performed. Specifically, buffer layer 121 is formed on the front-side surface of substrate 102. Buffer layer 121 is formed on main surface 20A (see FIG. 3) of SiC layer 20 of silicon carbide substrate 1 employed as substrate 102. As buffer layer 121, an epitaxial layer is formed which is made of silicon carbide of n type conductivity and has a thickness of 0.5 μm, for example. Buffer layer 121 has a conductive impurity at a density of, for example, 5×10¹⁷ cm⁻³. Then, on buffer layer 121, reverse breakdown voltage holding layer 122 is formed as shown in FIG. 12. As reverse breakdown voltage holding layer 122, a layer made of silicon carbide of n type conductivity is formed using an epitaxial growth method. Reverse breakdown voltage holding layer 122 can have a thickness of, for example, 10 μm. Further, reverse breakdown voltage holding layer 122 includes an impurity of n type conductivity at a density of, for example, 5×10¹⁵ cm⁻³.

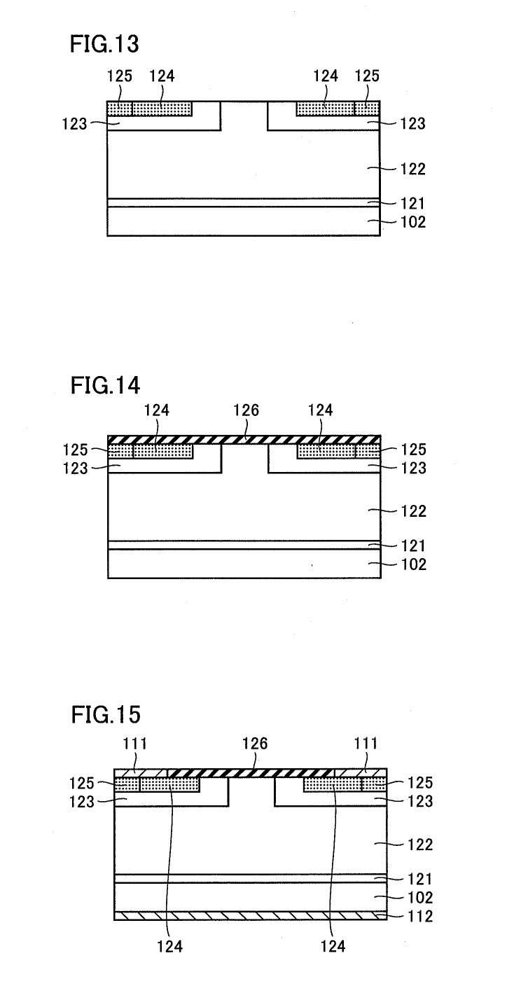

Next, as shown in FIG. 11, an implantation step (S130) is performed. Specifically, an impurity of p type conductivity is implanted into reverse breakdown voltage holding layer 122 using, as a mask, an oxide film formed through photolithography and etching, thereby forming p regions 123 as shown in FIG. 13. Further, after removing the oxide film thus used, an oxide film having a new pattern is formed through photolithography and etching. Using this oxide film as a mask, a conductive impurity of n type conductivity is implanted into predetermined regions to form n⁺ regions 124. In a similar way, a conductive impurity of p type conductivity is implanted to form p⁺ regions 125. As a result, the structure shown in FIG. 13 is obtained.

After such an implantation step, an activation annealing process is performed. This activation annealing process can be performed under conditions that, for example, argon gas is employed as atmospheric gas, heating temperature is set at 1700° C., and heating time is set at 30 minutes.

Next, a gate insulating film forming step (S140) is performed as shown in FIG. 11. Specifically, as shown in FIG. 14, oxide film 126 is formed to cover reverse breakdown voltage holding layer 122, p regions 123, n⁺ regions 124, and p⁺ regions 125. As a condition for forming oxide film 126, for example, dry oxidation (thermal oxidation) may be performed. The dry oxidation can be performed under conditions that the heating temperature is set at 1200° C. and the heating time is set at 30 minutes.

Thereafter, a nitrogen annealing step (S150) is performed as shown in FIG. 11. Specifically, an annealing process is performed in atmospheric gas of nitrogen monoxide (NO). Temperature conditions for this annealing process are, for example, as follows: the heating temperature is 1100° C. and the heating time is 120 minutes. As a result, nitrogen atoms are introduced into a vicinity of the interface between oxide film 126 and each of reverse breakdown voltage holding layer 122, p regions 123, n⁺ regions 124, and p⁺ regions 125, which are disposed below oxide film 126. Further, after the annealing step using the atmospheric gas of nitrogen monoxide, additional annealing may be performed using argon (Ar) gas, which is an inert gas. Specifically, using the atmospheric gas of argon gas, the additional annealing may be performed under conditions that the heating temperature is set at 1100° C. and the heating time is set at 60 minutes.

Next, as shown in FIG. 11, an electrode forming step (S160) is performed. Specifically, a resist film having a pattern is formed on oxide film 126 by means of the photolithography method. Using the resist film as a mask, portions of the oxide film above n⁺ regions 124 and p⁺ regions 125 are removed by etching. Thereafter, a conductive film such as a metal is formed on the resist film and formed in openings of oxide film 126 in contact with n⁺ regions 124 and p⁺ regions 125. Thereafter, the resist film is removed, thus removing the conductive film's portions located on the resist film (lift-off). Here, as the conductor, nickel (Ni) can be used, for example. As a result, as shown in FIG. 15, source electrodes 111 can be obtained. It should be noted that on this occasion, heat treatment for alloying is preferably performed. Specifically, using atmospheric gas of argon (Ar) gas, which is an inert gas, the heat treatment (alloying treatment) is performed with the heating temperature being set at 950° C. and the heating time being set at 2 minutes.

Thereafter, on source electrodes 111, upper source electrodes 127 (see FIG. 10) are formed. Further, gate electrode 110 (see FIG. 10) is formed on oxide film 126. Furthermore, drain electrode 112 is formed. In this way, semiconductor device 101 shown in FIG. 10 can be obtained.

It should be noted that in the fourth embodiment, the vertical type MOSFET has been illustrated as one exemplary semiconductor device that can be fabricated using the silicon carbide substrate of the present invention, but the semiconductor device that can be fabricated is not limited to this. For example, various types of semiconductor devices can be fabricated using the silicon carbide substrate of the present invention, such as a JFET (Junction Field Effect Transistor), an IGBT (Insulated Gate Bipolar Transistor), and a Schottky barrier diode.

Further, the fourth embodiment has illustrated a case where the semiconductor device is fabricated by forming the epitaxial layer, which serves as an active layer, on the silicon carbide substrate having its main surface corresponding to the (03-38) plane. However, the crystal plane that can be adopted for the main surface is not limited to this and any crystal plane suitable for the purpose of use and including the (0001) plane can be adopted for the main surface.

Further, as the main surface (main surface 20A of SiC substrate (SiC layer) 20 of silicon carbide substrate 1), there can be adopted a main surface having an off angle of not less than −3° and not more than +5° relative to the (0-33-8) plane in the <01-10> direction, so as to further improve channel mobility in the case where a MOSFET or the like is fabricated using the silicon carbide substrate. Here, the (0001) plane of single-crystal silicon carbide of hexagonal crystal is defined as the silicon plane whereas the (000-1) plane is defined as the carbon plane. Meanwhile, the “off angle relative to the (0-33-8) plane in the <01-10> direction” refers to an angle formed by the orthogonal projection of a normal line of the main surface to a flat plane defined by the <000-1> direction and the <01-10> direction serving as a reference for the off orientation, and a normal line of the (0-33-8) plane. The sign of a positive value corresponds to a case where the orthogonal projection approaches in parallel with the <01-10> direction, whereas the sign of a negative value corresponds to a case where the orthogonal projection approaches in parallel with the <000-1> direction. Further, the expression “the main surface having an off angle of not less than −3° and not more than +5° relative to the (0-33-8) plane in the <01-10> direction” indicates that the main surface corresponds to a plane, at the carbon plane side, which satisfies the above-described conditions in the silicon carbide crystal. It should be noted that in the present application, the (0-33-8) plane includes an equivalent plane, at the carbon plane side, which is expressed in a different manner due to determination of an axis for defining a crystal plane, and does not include a plane at the silicon plane side.

### Example

In order to confirm the effects provided by the method for manufacturing the silicon carbide substrate in the present invention, an experiment was conducted to manufacture a silicon carbide substrate, in accordance with the same procedure as that in each of the above-described third embodiment. The experiment was conducted in the following manner.

First, as the base substrate, a substrate was prepared which was made of single-crystal silicon carbide and had a diameter φ of 2 inches, a thickness of 300 μm, a polytype of 4H, a main surface corresponding to the (03-38) plane, an n type impurity concentration of 1×10²⁰ cm⁻³, a micro pipe density of 1×10⁴ cm⁻², and a stacking fault density of 1×10⁵ cm⁻¹. Meanwhile, as the SiC substrate, a substrate was prepared which was made of single-crystal silicon carbide, had a planar shape of square having each side of 20 mm, had a thickness of 300 μm, had a polytype of 4H, had a main surface corresponding to the (03-38) plane, had an n type impurity concentration of 1×10¹⁹ cm⁻³, had a micro pipe density of 0.2 cm⁻², and had a stacking fault density of less than 1 cm⁻¹.

Next, a plurality of the SiC substrates were placed and arranged side by side on the base substrate so as not to overlap with one another, thereby obtaining a stacked substrate. The stacked substrate thus obtained was then placed in a container (crucible) made of graphite and having an inner wall provided with a coating layer made of silicon carbide. Then, the stacked substrate was heated to reach or exceed 2000° C. to connect the base substrate and the SiC substrates to one another. Meanwhile, for comparison, experiment was conducted in the same procedure, for a container (crucible) not having the coating layer formed thereon.

As a result, as compared with the case where no coating layer is formed, graphitization was restrained in the vicinity of surfaces of the base substrate and the SiC substrates by forming the coating layer, thereby achieving good connection between the base substrate and each of the SiC substrates. It is considered that this is due to the following reason. That is, sublimation gas from the coating layer caused increase of vapor pressure of the sublimation gas in the crucible, thereby restraining selective (preferential) desorption of silicon.

It should be noted that the base substrate (base layer) preferably has a diameter of 2 inches or greater, more preferably, 6 inches or greater in the method for manufacturing the silicon carbide substrate, the method for manufacturing the semiconductor device, the silicon carbide substrate, and the semiconductor device in the present invention. Further, in consideration of application thereof to a power device, silicon carbide constituting the SiC layer (SiC substrate) preferably has a polytype of 4H. In addition, each of the base substrate and the SiC substrate preferably has the same crystal structure. Moreover, a difference in thermal expansion coefficient between the base layer and the SiC layer is preferably small enough to generate no cracks in the process of manufacturing the semiconductor device using the silicon carbide substrate. Further, in each of the base substrate and the SiC substrate, variation in the thickness thereof is small, specifically, the variation of the thickness thereof is preferably 10 μm or smaller. Meanwhile, in consideration of application thereof to a vertical type device in which electric current flows in the direction of thickness of the silicon carbide substrate, the base layer preferably has an electrical resistivity of less than 50 mΩcm, more preferably, less than 10 mΩcm. Meanwhile, in order to facilitate handling thereof, the silicon carbide substrate preferably has a thickness of 300 μm or greater. Further, the heating of the base substrate in the step of forming the base substrate can be performed using, for example, a resistive heating method, a high-frequency induction heating method, a lamp annealing method, or the like.

The method for manufacturing the silicon carbide substrate, the method for manufacturing the semiconductor device, the silicon carbide substrate, and the semiconductor device in the present invention are particularly advantageously applicable to a method for manufacturing a silicon carbide substrate, a method for manufacturing a semiconductor device, a silicon carbide substrate, and a semiconductor device, each of which is required to achieve reduced manufacturing cost of a semiconductor device that employs a silicon carbide substrate.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A method for manufacturing a silicon carbide substrate, comprising the steps of:
preparing a SiC substrate made of single-crystal silicon carbide;
disposing a silicon carbide source in a container so as to face a main surface of said SiC substrate; and
forming a base layer made of silicon carbide in contact with the main surface of said SiC substrate by heating said silicon carbide source in said container to fall within a range of temperature equal to or higher than a sublimation temperature of silicon carbide constituting said silicon carbide source,
said container having an inner wall, at least a portion of which is provided with a coating layer made of silicon carbide.

2. The method for manufacturing the silicon carbide substrate according to claim 1, wherein said coating layer is formed all over said inner wall of said container.

3. The method for manufacturing the silicon carbide substrate according to claim 1, wherein said coating layer has a thickness of not less than 1 μm.

4. The method for manufacturing the silicon carbide substrate according to claim 1, wherein in the step of forming said base layer, said coating layer is heated to fall within a range of temperature higher than that of said silicon carbide source.

5. The method for manufacturing the silicon carbide substrate according to claim 1, wherein graphite is employed as a material to form said container.

6. The method for manufacturing the silicon carbide substrate according to claim 1, wherein:
in the step of preparing said SiC substrate, a plurality of said SiC substrates are prepared,
in the step of disposing said silicon carbide source, said silicon carbide source is disposed with the plurality of said SiC substrates being arranged side by side when viewed in a planar view, and
in the step of forming said base layer, said base layer is formed to connect the main surfaces of the plurality of said SiC substrates to each other.

7. The method for manufacturing the silicon carbide substrate according to claim 1, wherein:
in the step of disposing said silicon carbide source, as said silicon carbide source, a base substrate made of silicon carbide is disposed such that a main surface of said base substrate and the main surface of said SiC substrate face and make contact with each other, and
in the step of forming said base layer, said base layer is formed by heating said base substrate to connect said base substrate to said SiC substrate.

8. The method for manufacturing the silicon carbide substrate according to claim 7, further comprising the step of smoothing the main surfaces of said base substrate and said SiC substrate which are to be brought into contact with each other in the step of disposing said silicon carbide source, before the step of disposing said silicon carbide source.

9. The method for manufacturing the silicon carbide substrate according to claim 7, wherein the step of disposing said silicon carbide source is performed without polishing, before the step of disposing said silicon carbide source, the main surfaces of said base substrate and said SiC substrate which are to be brought into contact with each other in the step of disposing said silicon carbide source.

10. The method for manufacturing the silicon carbide substrate according to claim 1, wherein:
in the step of disposing said silicon carbide source, as said silicon carbide source, a material substrate made of silicon carbide is disposed such that a main surface of said material substrate and the main surface of said SiC substrate face each other with a space therebetween, and
in the step of forming said base layer, said base layer is formed by heating said material substrate to sublimate silicon carbide constituting said material substrate.

11. The method for manufacturing the silicon carbide substrate according to claim 1, wherein in the step of forming said base layer, said base layer is formed such that an opposite main surface of said SiC substrate to said base layer has an off angle of not less than 50° and not more than 65° relative to a {0001} plane.

12. The method for manufacturing the silicon carbide substrate according to claim 11, wherein in the step of forming said base layer, said base layer is formed such that the opposite main surface of said SiC substrate to said base layer has an off orientation forming an angle of not more than 5° relative to a <1-100> direction.

13. The method for manufacturing the silicon carbide substrate according to claim 12, wherein in the step of forming said base layer, said base layer is formed such that the opposite main surface of said SiC substrate to said base layer has an off angle of not less than −3° and not more than 5° relative to a {03-38} plane in the <1-100> direction.

14. The method for manufacturing the silicon carbide substrate according to claim 11, wherein in the step of forming said base layer, said base layer is formed such that the opposite main surface of said SiC substrate to said base layer has an off orientation forming an angle of not more than 5° relative to a <11-20> direction.

15. The method for manufacturing the silicon carbide substrate according to claim 1, wherein in the step of forming said base layer, said base layer is formed in an atmosphere obtained by reducing pressure of atmospheric air.

16. The method for manufacturing the silicon carbide substrate according to claim 1, wherein in the step of forming said base layer, said base layer is formed under a pressure higher than 10⁻¹ Pa and lower than 10⁴ Pa.

17. A method for manufacturing a semiconductor device, comprising the steps of:
preparing a silicon carbide substrate;
forming an epitaxial growth layer on said silicon carbide substrate; and
forming an electrode on said epitaxial growth layer,
in the step of preparing said silicon carbide substrate, said silicon carbide substrate being manufactured using the method for manufacturing the silicon carbide substrate as recited in claim 1.

18. A silicon carbide substrate manufactured using the method for manufacturing the silicon carbide substrate as recited in claim 1.

19. A semiconductor device manufactured using the method for manufacturing the semiconductor device as recited in claim 17.
